(19) United States
(12) Patent Application Publication
(10) Pub. No.: US 2023/0195962 A1
(43) Pub. Date: Jun. 22, 2023

(54) MODEL CONSTRUCTION APPARATUS, ESTIMATION APPARATUS, MODEL CONSTRUCTION METHOD, ESTIMATION METHOD AND PROGRAM

(71) Applicant: Nippon Telegraph and Telephone Corporation, Tokyo (JP)

(72) Inventors: Yoichi Matsuo, Musashino-shi, Tokyo (JP); Keishiro WATANABE, Musashino-shi, Tokyo (JP)

(21) Appl. No.: 17/925,885

(22) PCT Filed: Jun. 3, 2020
(86) PCT No.: PCT/JP2020/022008

§ 371 Date: Nov. 17, 2022

(51) Int. Cl. G06F 30/20

(52) U.S. Cl. CPC G06F 30/20

(57) ABSTRACT

A model construction apparatus according to an embodiment includes a processor and a memory storing program instructions that cause the processor to receive pieces of observed data from a communication network system that is a target for estimation of a location or a cause of an abnormality; divide the received pieces of observed data into a plurality of clusters according to the types of information represented by the respective pieces of observed data; determine, for each location or each cause of an abnormality, a representative value as representative observed data for each of the plurality of clusters; and construct, using the representative observed data, a first causal model for estimating the location or the cause of the abnormality from the pieces of observed data based on a rule-based method.

### TECHNICAL FIELD

The present invention relates to a model construction apparatus, an estimation apparatus, a model construction method, an estimation method, and a program.

### BACKGROUND ART

For communication common carriers, grasping an abnormal state that occurs in a communication network system and promptly dealing with the abnormal state is an important task. Thus, research has been performed so far on a method for detecting an abnormality that has occurred in a communication network system in an early stage, and a method for estimating a location or a cause of an abnormality, for example.

As a method for estimating a location or a cause of an abnormality, there has been proposed a method that includes modeling the relationship between a location or a cause of an abnormality and changes in data (hereinafter also referred to as “observed data”) in a communication network system caused due to the abnormality as a causal model, using a Bayesian network, and then estimating a location or a cause of an abnormality from observed data when an abnormality has occurred (Non-Patent Literatures 1 to 3). Such a method can be classified as either a rule-based method or a data-driven method.

A rule-based method is a method of constructing a model based on a pre-defined rule. In the rule-based method, the relationship between a location or a cause of an abnormality and changes in observed data is modeled using mainly the knowledge of an expert, such as an operator of a communication network system. For example, in Non-Patent Literature 1, a rule, which defines that each router in a normal or abnormal state affects only observed data of an adjacent link, is created from the knowledge of an expert, and a causal model is constructed using such a rule and the adjacency relationship of the topology of a communication network system. In addition, Non-Patent Literature 2 proposes creating a template as an abstract rule to facilitate the construction of a causal model.

A data-driven method is a method of constructing a model from data. In the data-driven method, the relationship between a location or a cause of an abnormality and changes in observed data when the abnormality has occurred is modeled using observed data when an abnormality occurred in the past. For example, in Non-Patent Literature 3, the relationship between a failure and changes in observed data is modeled using data on a plurality of case examples obtained in the past.

It should be noted that, in the method for estimating a location or a cause of an abnormality, a location or a cause of an abnormality is estimated using syslog or traffic information of a communication network system, for example. However, in recent years, it has become possible to easily obtain not only syslog or traffic information but also various types of observed data, such as flow data, telemetry data, and sensor data related to a communication device, for example. Thus, it is considered that using such various types of observed data can estimate a location or a cause of an abnormality with finer granularity.

### CITATION LIST

### Non-Patent Literature

Non-Patent Literature 1: Srikanth Kandula, Dina Katabi, and Jean-philippe Vasseur. Shrink: A tool for failure diagnosis in IP networks. Proceedings of the 2005 ACM SIGCOMM workshop on Mining network data, pages 173-178, 2005.

Non-Patent Literature 2: He Yan, Lee Breslau, Zihui Ge, Dan Massey, Dan Pei, and Jennifer Yates. G-RCA: A Generic Root Cause Analysis Platform for Service Quality Management in Large IP Networks. IEEE/ACM Transactions on Networking, 20(6):1734-1747, 2012.

Non-Patent Literature 3: Kandula, Srikanth and Mahajan, Ratul and Verkaik, Patrick and Agarwal, Sharad and Padhye, Jitendra and Bahl, Paramvir. Detailed diagnosis in enterprise networks. ACM SIGCOMM Computer Communication Review, vol. 39, num. 4, pp.243-254, 2009.

### SUMMARY OF THE INVENTION

### Technical Problem

However, when a causal model is constructed using various types of observed data, the following problems arise.

Problem 1: With a rule-based method, which requires the knowledge of an expert in advance for constructing a model, it is difficult to establish a rule for the relationship between an abnormality that occurs in a communication network system and each piece of various types of observed data one by one.

Problem 2: A data-driven method requires observed data when an abnormality occurred in the past, but typically, an abnormality does not occur frequently in a communication network system. Further, when the types of observed data are various, the number of patterns of the various types of observed data with respect to an abnormality is increased correspondingly. Thus, it is typically difficult to collect abnormal case examples corresponding to the increased number of patterns.

Problem 3: Further, in recent years, there have been increasing cases where a topology changes frequently with the development of a virtualization technique for a communication network. Along with this, observed data obtained from a communication network system also changes frequently. Therefore, with a rule-based method, it is difficult to establish a rule for the relationship between an abnormality and each piece of observed data one by one, while with a data-driven method, it is difficult to collect sufficient abnormal case examples.

An embodiment of the present invention has been made in view of the foregoing, and it is an object of the present invention to construct a causal model for estimating a location or a cause of an abnormality using various types of observed data.

### Means for Solving the Problem

To solve the aforementioned object, a model construction apparatus according to an embodiment includes a collection unit that collects pieces of observed data from a communication network system that is a target for estimation of a location or a cause of an abnormality; a division unit that divides the pieces of observed data collected by the collection unit into a plurality of clusters according to types of information represented by the respective pieces of observed data; a determination unit that determines, for each location or each cause of an abnormality, a representative value as representative observed data for each of the plurality of clusters; and a first model construction unit that constructs, using the representative observed data, a first causal model for estimating the location or the cause of the abnormality from the pieces of observed data based on a rule-based method.

### Effects of the Invention

It is possible to construct a causal model for estimating a location or a cause of an abnormality using various types of observed data.

### BRIEF DESCRIPTION OF DRAWINGS

FIG. 1 is a view illustrating an exemplary graphical model.

FIG. 2 is a diagram illustrating an exemplary functional configuration of an estimation apparatus according to the present embodiment.

FIG. 3 is a flowchart illustrating an exemplary process of constructing a causal model according to the present embodiment.

FIG. 4 is a flowchart illustrating an exemplary process of estimating a location or a cause of an abnormality according to the present embodiment.

FIG. 5 is a diagram illustrating an exemplary hardware configuration of the estimation apparatus according to the present embodiment.

### DESCRIPTION OF EMBODIMENTS

Hereinafter, an embodiment of the present invention will be described. In the present embodiment, an estimation apparatus 10 will be described that constructs a causal model from various types of observed data in a communication network system, and estimates a location or a cause of an abnormality in the communication network system using the causal model. Herein, the estimation apparatus 10 according to the present embodiment includes a “model construction phase” in which a causal model is constructed from observed data obtained in the past, and an “estimation phase” in which a location or a cause of an abnormality is estimated from observed data when an abnormality has occurred, using the causal model. It should be noted that the estimation apparatus 10 in the model construction phase may also be referred to as a “model construction apparatus,” for example. In addition, the communication network system is a system that implements a communication network environment having various devices (for example, a router and a server) as nodes, and having communication paths and the like as links, and may also be referred to as an information and communication technology (ICT) system, for example.

### Theoretical Configuration

Described first is a theoretical configuration related to the construction of a causal model in the model construction phase and the estimation of a location or a cause of an abnormality in the estimation phase.

In the present embodiment, two causal models are constructed using a rule-based method and a data-driven method, respectively, for various types of observed data, taking into account Problem 1 and Problem 2 described above (hereinafter also referred to as a “rule-based causal model” and a “data-driven causal model”). Then, a new causal model is constructed by combining the rule-based causal model and the data-driven causal model so that Problem 3 described above is solved. Using such a causal model allows for the estimation of a location or a cause of an abnormality from various types of observed data. It should be noted that each of such causal models is represented by a Bayesian network as one of graphical models.

Hereinafter, a case where a location of an abnormality is estimated is supposed, for example, and a case will be described where an apparatus in which an abnormality has occurred is estimated as a point in which an abnormality has occurred in a communication network system. It should be noted that when an apparatus i described below is assumed as a cause i, the following description is similarly applicable to the estimation of a cause.

It is assumed that the state of the apparatus i in the communication network system is represented by xᵢ, where i∈{1, . . . , N}, and the state of observed data j is represented by yⱼ, where j∈{1, . . . , M}. N represents the number of apparatuses forming the communication network system, and M represents the number of pieces of observed data. It is assumed that each of xᵢ and yⱼ has a value of either 0 (i.e., a normal state) or 1 (i.e., an abnormal state). However, each of xᵢ and yⱼ may have not a binary value of 0 or 1 but a multilevel value of a ternary value or greater.

In addition, the prior probability P(xᵢ) and the conditional probability P(yⱼ|xᵢ) are defined for each of xᵢ and yⱼ, and the posterior probability P(xᵢ|yⱼ) is constructed as a causal model.

It should be noted that as the observed data j, it is possible to use not only various types of data (for example, syslog, traffic information, flow data, telemetry data, and sensor data) that can be collected from the communication network system but also the causal degree described in a reference document “Yasuhiro Ikeda, Keisuke Ishibashi, Yuusuke Nakano, Keishiro Watanabe, Ryoichi Kawahara, “Anomaly Detection and Interpretation using Multimodal Autoencoder and Sparse Optimization”, arXiv:1812.07136 [stat.ML],” for example.

The state yⱼ of the observed data j may be determined by, for example, when the observed data j (which may include the causal degree) is a continuous value, determining a threshold from the value of the observed data j in the normal state, and then setting the value of the state yⱼ of the observed data j that is greater than or equal to (or less than or equal to) the threshold to 1, and setting other values of the state yⱼ of the observed data j to 0, or calculating the dispersion of the observed data j in the normal state and then setting the value of the state yⱼ of the observed data j that is outside L (where L is a predetermined given natural number) sigmas to 1, and setting other values of the state yⱼ of the observed data j to 0.

### Construction of Rule-Based Causal Model

A method for constructing a rule-based causal model that solves Problem 1 described above will be described. In the present embodiment, the states of pieces of observed data are divided into a plurality of clusters, and the representative values of the respective clusters are used as the new states of the pieces of observed data. Accordingly, it is possible to reduce the number of the states of the pieces of observed data (that is, reduce the number of pieces of observed data used for constructing a rule-based causal model), and thus solve Problem 1.

Herein, the pieces of observed data include those obtained from the entire communication network system and those obtained from each apparatus. Such pieces of data represent different pieces of information. For example, observed data, such as the usage rate of a central processing unit (CPU)/memory and telemetry data on temperature and the like, represents the internal state of each apparatus, and observed data, such as the input/output traffic amount and an interface trap, represents the input or output among the apparatuses, and further, observed data, such as Netflow information and round-trip time (RTT), represents the state of the entire communication network system. Further, observed data, which represents the internal state of each apparatus or the input or output among the apparatuses, may represent different information depending on which apparatus's internal state or input/output is represented.

Herein, in the present embodiment, the states yⱼ of the pieces of observed data j are divided into three types including Type 1 to Type 3 as follows according to the types of information represented by the respective pieces of observed data j.

Type 1: the state y_{i,j}¹ (where i∈{1, . . . , N} and j∈{1, . . . , Mᵢ¹}) of the observed data representing the state xᵢ of the apparatus i

Type 2: the state y_{i,j}² (where i∈{1, . . . , N} and j∈{1, . . . , Mᵢ²}) of the observed data representing an input to or output from the apparatus i

Type 3: the state yⱼ³ (where j∈{1, . . . , M³}) of the observed data representing the state of the entire communication network system.

It should be noted that M=Σᵢ(Mᵢ¹+Mᵢ²)+M³.

In this manner, the states yⱼ of the pieces of observed data j (where j=1, . . . , M) are divided into three clusters of Type 1 to Type 3. Accordingly, the pieces of observed data j (where j=1, . . . , M) are also divided into three clusters of Type 1 to Type 3.

Then, for each of i=1, . . . , N, the representative value zᵢ¹ of y_{i,j}¹, the representative value zᵢ² of y_{i,j}², and the representative value z³ of yⱼ³ are created. It is assumed that each of the representative values zᵢ¹, zᵢ² and z³ has a value of either 0 (i.e., a normal state) or 1 (i.e., an abnormal state). The value of each of the representative values zᵢ¹, zᵢ² and z³ may be determined in various ways. For example, a method of setting zᵢ¹ to 1 if predetermined k or more values among y_{i,j}¹ (where j=1, . . . , Mᵢ¹) are 1 is considered. For each of zᵢ² and z³ also, a method of setting zᵢ² to 1 if k or more values among y_{i,j}² (where j=1, . . . , Mᵢ²) are 1 is considered, and a method of setting z³ to 1 if k or more values among yⱼ³ (where j=1, . . . , M³) are 1 is considered. It should be noted that k may be either a common value or differ values among the clusters.

Then, a rule-based causal model is constructed for the representative values zᵢ¹, zᵢ² and z³ and the states xᵢ of the apparatuses i, using a given known rule-based method. That is, the prior probability P(x₁, . . . , x_{N}) and the conditional probability P (z₁¹, z₁², . . . , z_{N}¹, z_{N}², z³|x₁, . . . , x_{N}) are defined using a given known rule-based method, and then, the posterior probability P(x₁, . . . , x_{N}|z₁¹, z₁², . . . , z_{N}¹, z_{N}², z³) is constructed as a rule-based causal model. In this manner, using the representative values zᵢ¹, zᵢ² and z³ instead of the states yⱼ of the pieces of observed data j can reduce the number of states of the pieces of observed data used for constructing the model, and thus can solve Problem 1 described above. It should be noted that the conditional probability P(z₁¹, z₁², . . . , z_{N}¹, z_{N}², z³|x₁, . . . , x_{N}) is the conditional probability Pᵣ described below.

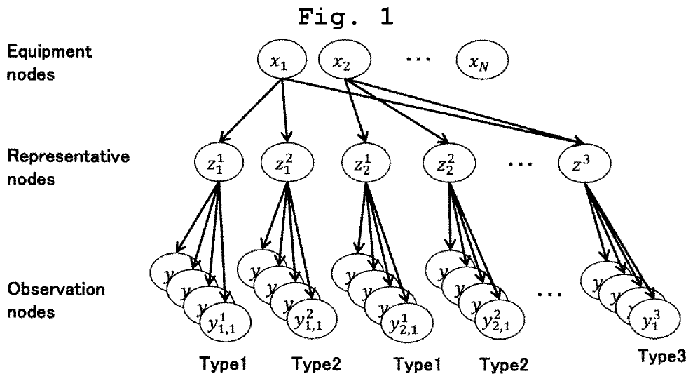

Herein, FIG. 1 illustrates an example of a graphical model (i.e., a Bayesian network) representing the causal model including the states y_{i,j}¹, y_{i,j}², and yⱼ³, the representative values zᵢ¹, zᵢ², and z³, and the states xᵢ as nodes. In the example illustrated in FIG. 1, the states y_{i,j}¹ and y_{i,j}² are represented as “Observation nodes,” the representative values zᵢ¹, zᵢ², and z³ are represented as “Representative nodes,” and the states xᵢ of the apparatuses i are represented as “Equipment nodes.” The causal relationship between the “Representative nodes” and the “Equipment nodes” is defined using a given known rule-based method.

Although the present embodiment illustrates an example in which the states yⱼ of the pieces of observed data j are divided into three clusters of Type 1 to Type 3, this is only exemplary, and the states yⱼ of the pieces of observed data j may be divided into any number of clusters.

### Construction of Data-Driven Causal Model

A method for constructing a data-driven causal model that solves Problem 2 described above will be described. In the present embodiment, a causal model is constructed using not only abnormal case examples but also normal case examples. Accordingly, even when it is difficult to collect abnormal case examples, it is possible to construct a causal model, and thus solve Problem 2.

When a causal model is constructed using a known data-driven method, the conditional probability P(y₁, . . . , y_{M}|xᵢ) is defined using the states yⱼ (where j=1, . . . , M) of the pieces of observed data j obtained when the state xᵢ of the apparatus i in the past was obtained so that a causal model is constructed. Herein, Problem 2 results from the fact that there are not many case examples in which the state xᵢ of the apparatus i was abnormal in the past, but in the communication network system, there are typically a number of case examples in which the state xᵢ is normal, and thus, there also exists the relationship between the state xi of the apparatus i and the states yⱼ of the pieces of observed data j when the state xᵢ is normal. Thus, in the present embodiment, a causal model is constructed by also using case examples in which the state xᵢ is normal.

The conditional probability Pₙₒᵣₘₐₗ(y₁, . . . , y_{M}|xᵢ) in the normal state is defined using the values of y₁, . . . , y_{M} when the state xᵢ of the apparatus i is normal. It should be noted that for the normal case examples, only case examples in which the states xᵢ of all apparatuses i as well as the states yⱼ of all pieces of observed data j are normal are obtained. Thus, the relationship between the pieces of observed data is calculated, and to this end, the conditional probability related to the pieces of observed data and apparatuses that obtain the pieces of observed data is determined as the value of the relationship. For example, observed data j′ obtained from an apparatus i′ and observed data j″ obtained from an apparatus i″ are considered, and the relationship of the observed data j″ with respect to the observed data j′ is calculated. To calculate such relationship, using the correlation coefficient, Granger causality, or the weight of an auto encoder obtained through learning with pieces of observed data in the normal state is considered, for example.

Then, provided that the relationship of the observed data j″ with respect to the observed data j′ is the conditional probability is defined as Pₙₒᵣₘₐₗ(y_{j″}|x_{i′})=Pₙₒᵣₘₐₗ(y_{j′}|x_{i″})=v_{i′}. To combine these, Pₙₒᵣₘₐₗ is defined as follows.

Pₙₒᵣₘₐₗ(y₁, . . . , y_{M}|x₁, . . . , x_{N})=ΠᵢPₙₒᵣₘₐₗ(y₁, . . . , y_{M}|xᵢ)=τ×Πᵢvᵢ

Herein, τ is a normalization constant.

Finally, the conditional probability P(y₁, . . . , y_{M}|x₁, . . . , x_{N}) is defined as follows .

P(y₁, . . . , y_{M}|x₁, . . . , x_{N})=W×Pₙₒᵣₘₐₗ(y₁, . . . , y_{M}|x₁, . . . , x_{N})×(1−W)×P_{abnormal}(y₁, . . . , y_{M}|x₁, . . . , x_{N})

Herein, P_{abnormal}(y₁, . . . , y_{M}|x₁, . . . , x_{N}) is the conditional probability defined with a given known data-driven method using abnormal case examples. In addition, W<1 is a preset weight parameter. In this manner, since it is supposed that the relationship in the normal state and the relationship in the abnormal state are different, the conditional probability Pₙₒᵣₘₐₗ representing the relationship in the normal state is weighted with W, and the conditional probability P_{abnormal} representing the relationship in the abnormal state is weighted with 1−W. It should be noted that the conditional probability P (or P_{abnormal}) defined as above is the conditional probability P_{d} described below.

Accordingly, the posterior probability P(x₁, . . . , x_{N}|y₁, . . . , y_{M}) can be constructed as a data-driven causal model from the prior probability P(x₁, . . . , x_{N}) and the conditional probability P(y₁, . . . , y_{M}|x₁, . . . , x_{N}). In this manner, using normal case examples in addition to abnormal case examples can solve Problem 2 described above.

### Combination of Rule-Based Causal Model and Data-Driven Causal Model

Finally, a method for constructing a causal model, which solves Problem 3 described above, by combining the rule-based causal model and the data-driven causal model will be described.

When the network configuration of a communication network system (for example, the topology of the communication network) or observed data and the like obtained from the communication network system changes frequently, it would be difficult to construct a causal model that covers all of the relationships in advance using a rule-based method or a data-driven method. However, modifying the conditional probability P(z₁¹, z₁², . . . , z_{N}¹, z_{N}², z³|x₁, . . . , x_{N}) based on the conditional probability Pₙₒᵣₘₐₗ defined using the normal case examples can construct a causal model for which the relationships in the actual communication network system are taken into account. It should be noted that the conditional probability P(z₁¹, z₁², . . . , z_{N}¹, z_{N}², z³|x₁, . . . , x_{N}) may also be expressed as P(y₁, . . . , y_{M}|x₁, . . . x_{N}) based on the definition of each of zᵢ¹, zᵢ² and z³.

That is, provided that the conditional probability defined in constructing the rule-based causal model is Pᵣ(y₁, . . . , y_{M}|x₁, . . . , x_{N}) and the conditional probability defined in constructing the data-driven causal model is P_{d}(y₁, . . . , y_{M}|x₁, . . . , x_{N}), a conditional probability P(y₁, . . . , y_{M}|x₁, . . . , x_{N}) is defined by modifying the conditional probability Pᵣ based on the conditional probability P_{d}. Then, the posterior probability P(x₁, . . . , x_{N}|y₁, . . . , y_{M}) is constructed as a causal model from the prior probability (x₁, . . . , x_{N}) and the conditional probability P(y₁, . . . , y_{M}|x₁, . . . , x_{N}). Accordingly, it is possible to obtain a causal model combining the rule-based causal model and the data-driven causal model, and thus solve Problem 3 described above.

Various methods may be used to modify the conditional probability Pᵣ based on the conditional probability P_{d}. For example, modifying the conditional probability Pᵣ as follows to obtain the conditional probability P(y₁, . . . , y_{M}|x₁, . . . , x_{N}) is considered.

P(y₁, . . . , y_{M}|x₁, . . . , x_{N})=α×Pᵣ(y₁, . . . , y_{M}|x₁, . . . , x_{N})×(1−α)×P_{d}(y₁, . . . , y_{M}|x₁, . . . , x_{N})

Herein, α is a preset weight parameter.

It should be noted that P_{d} is W×Pₙₒᵣₘₐₗ(y₁, . . . , y_{M}|x₁, . . . , x_{N})×(1−W)×P_{abnormal}(y₁, . . . , y_{M}|x₁, . . . , x_{N}) described above, but the present invention is not limited thereto. For example, P_{d} may be P_{abnormal} (y₁, . . . , y_{M}|x₁, . . . , x_{N}) (that is, P_{d} may be the conditional probability defined using the abnormal case examples).

### Functional Configuration

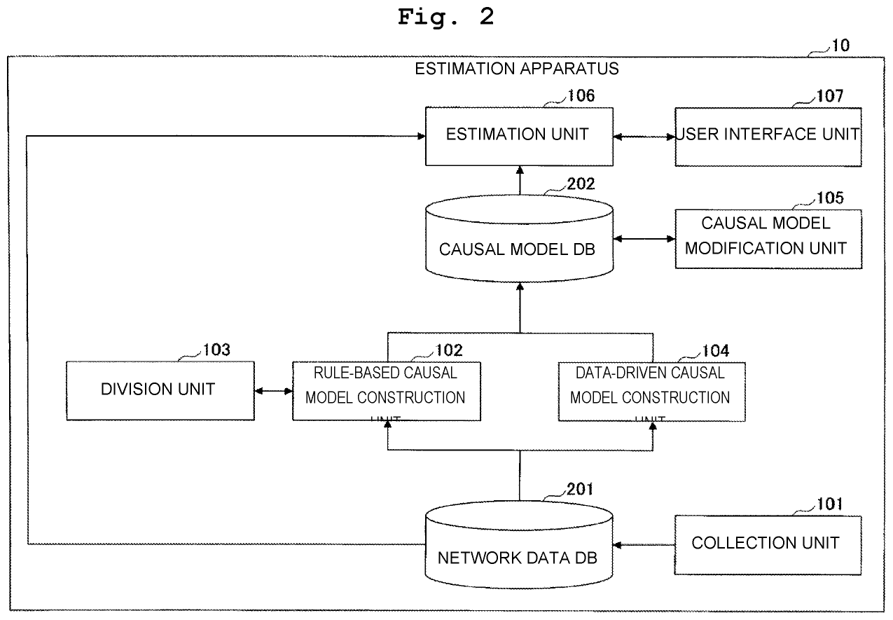

Next, the functional configuration of the estimation apparatus 10 according to the present embodiment will be described with reference to FIG. 2. FIG. 2 is a diagram illustrating an exemplary functional configuration of the estimation apparatus 10 according to the present embodiment.

As illustrated in FIG. 2, the estimation apparatus 10 according to the present embodiment includes a collection unit 101, a rule-based causal model construction unit 102, a division unit 103, a data-driven causal model construction unit 104, a causal model modification unit 105, an estimation unit 106, a user interface unit 107, a network data DB 201, and a causal model DB 202.

The collection unit 101 collects network configuration data and observed data from a communication network system. The network configuration data and the observed data collected by the collection unit 101 are stored in the network data DB 201. Herein, the network configuration data is information representing the topology of the communication network (that is, information representing the connection relationship among the apparatuses forming the communication network system, for example). With the network configuration data, the apparatus i, where i∈{1, . . . , N} and its connection relationship are identified, for example.

The rule-based causal model construction unit 102 calculates the representative values (for example, zᵢ¹ (where i=1, . . . , N), zᵢ² (where i=1, . . . , N), and z³ described above) for the respective clusters obtained through division by the division unit 103 described below, and then constructs the posterior probability as a rule-based causal model using the prior probability of the state of each apparatus and the conditional probability representing the relationship between each representative value and the state of each apparatus. The rule-based causal model constructed by the rule-based causal model construction unit 102 and the conditional probability calculated in constructing the model are stored in the causal model DB 202.

When the rule-based causal model is constructed by the rule-based causal model construction unit 102, the division unit 103 divides the states yⱼ of the pieces of observed data j into a plurality of clusters (for example, three clusters of Type 1 to Type 3 described above) according to type.

The data-driven causal model construction unit 104 calculates the relationship between pieces of observed data of normal case examples, and then calculates the conditional probability in the normal state using the calculated relationship. Then, the data-driven causal model construction unit 104 constructs the posterior probability as a data-driven causal model using the prior probability of the state of each apparatus, the conditional probability in the normal state, and the conditional probability in the abnormal state calculated with a given known data-driven method. The data-driven causal model constructed by the data-driven causal model construction unit 104 and the conditional probability calculated in constructing the model are stored in the causal model DB 202.

The causal model modification unit 105 modifies the conditional probability obtained in constructing the rule-based causal model, using the conditional probability obtained in constructing the data-driven causal model, and thus constructs a causal model combining the rule-based causal model and the data-driven causal model. The causal model combining the rule-based causal model and the data-driven causal model is stored in the causal model DB 202.

The estimation unit 106 estimates a location or a cause of an abnormality using one of the rule-based causal model, the data-driven causal model, or the causal model combining the rule-based causal model and the data-driven causal model. It should be noted that an apparatus or a cause corresponding to xᵢ having the maximum posterior probability (that is, ArgmaxᵢP(x₁, . . . , x_{N}|y₁, . . . , y_{M})) is a location or a cause of an abnormality.

The user interface unit 107 presents to a user (for example, an operator of the communication network system) the location or the cause of the abnormality estimated by the estimation unit 106 and its probability.

### Process of Constructing Causal Model

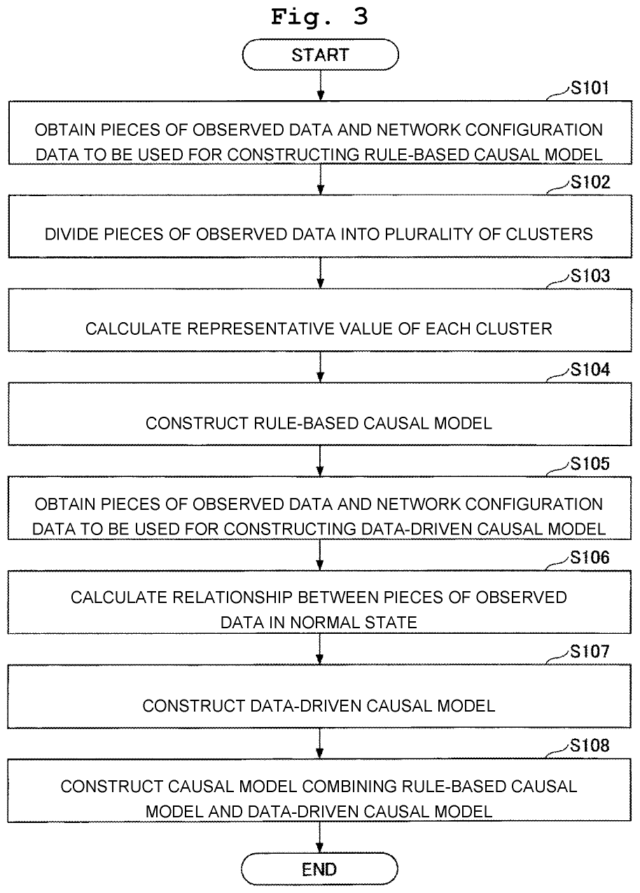

Next, a process performed in constructing a causal model with the estimation apparatus 10 according to the present embodiment in the model construction phase will be described with reference to FIG. 3. FIG. 3 is a flowchart illustrating an exemplary process of constructing a causal model according to the present embodiment. It should be noted that hereinafter, it is assumed that network configuration data and pieces of observed data collected by the collection unit 101 are stored in the network data DB 201. It is also assumed that the values of the states yⱼ of the pieces of observed data j collected by the collection unit 101 are calculated, and the pieces of observed data j and their states yⱼ are associated with each other to be stored in the network data DB 201.

Step S101: The rule-based causal model construction unit 102 obtains from the network data DB 201 pieces of observed data j obtained in the past, their states yⱼ, and the network configuration data to be used for constructing a model. It should be noted that the network configuration data is information representing the topology of the communication network, and includes identification information (that is, i=1, . . . , N) on apparatuses forming the communication network system, and the connection relationship among the apparatuses.

Step S102: Next, the division unit 103 divides the states yⱼ (where j=1, . . . , M) obtained in step S101 described above into a plurality of clusters according to the types of information represented by the respective pieces of observed data j. Hereinafter, it is assumed that the states yⱼ (where j=1, . . . , M) are divided into three clusters of Type 1 to Type 3 described above.

In step S103: Next, the rule-based causal model construction unit 102 calculates the representative values of the respective clusters obtained through division in step S102 described above. That is, the rule-based causal model construction unit 102 calculates the representative value zᵢ¹ (where i=1, . . . , N) of the cluster of Type 1, the representative value zᵢ² (where i=1, . . . , N) of the cluster of Type 2, and the representative value z³ of the cluster of Type 3.

Step S104: The rule-based causal model construction unit 102 calculates the prior probability of the state xᵢ of each apparatus i, and the conditional probability Pᵣ representing the relationship between each of the representative value zᵢ¹ (where i=1, . . . , N), the representative value zᵢ² (where i=1, . . . , N), and the representative value z³ calculated in step S103 described above and the state xᵢ of each apparatus i, using a given known rule-based method, and then constructs the posterior probability as a rule-based causal model from the prior probability and the conditional probability Pᵣ. It should be noted that the rule-based causal model and the conditional probability Pᵣ are stored in the causal model DB 202.

Step S105: The data-driven causal model construction unit 104 obtains from the network data DB 201 pieces of observed data j obtained in the past, their states yⱼ, and the network configuration data to be used for constructing a model.

Step S106: The data-driven causal model construction unit 104 calculates the relationship vᵢ between the pieces of observed data j in the normal state.

In step S107: The data-driven causal model construction unit 104 calculates the conditional probability P_{d} using the conditional probability Pₙₒᵣₘₐₗ defined by the relationship vᵢ and the conditional probability P_{abnormal} calculated with a given known data-driven method, and then constructs the posterior probability as a data-driven causal model from the prior probability of the state xᵢ of each apparatus i and the conditional probability P_{d}. It should be noted that the data-driven causal model and the conditional probability P_{d} are stored in the causal model DB 202.

Step S108: The causal model modification unit 105 calculates the conditional probability by modifying the conditional probability Pᵣ based on the conditional probability P_{d}. That is, the causal model modification unit 105 calculates the conditional probability P from P=α×Pᵣ×(1−α)×P_{d} as described above, for example. Then, the causal model modification unit 105 constructs the posterior probability as a causal model from the prior probability of the state xᵢ of each apparatus i and the conditional probability P. Accordingly, a causal model combining the rule-based causal model and the data-driven causal model is constructed. It should be noted that the causal model combining the rule-based causal model and the data-driven causal model is stored in the causal model DB 202.

Accordingly, in the model construction phase, the estimation apparatus 10 according to the present embodiment can construct each of the rule-based causal model and the data-driven causal model and then construct a causal model combining the rule-based causal model and the data-driven causal model. Accordingly, a causal model that solves Problem 1, Problem 2, and Problem 3 described above can be obtained.

### Process of Estimating Location or Cause of Abnormality

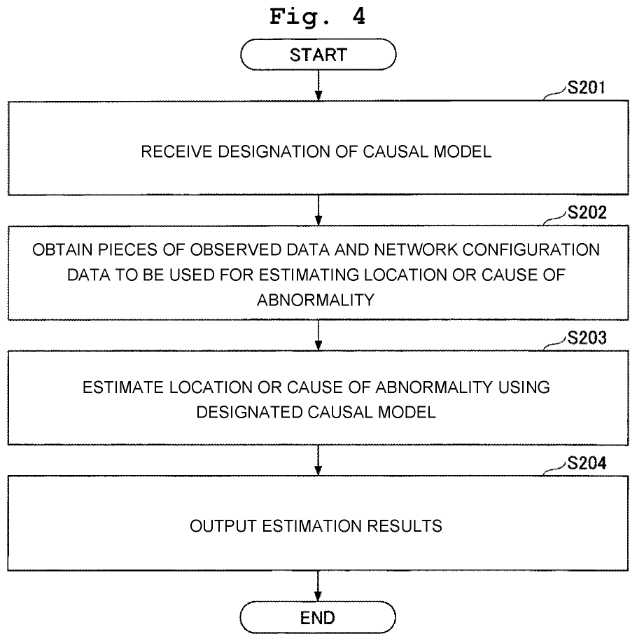

Next, a process performed in estimating a location or a cause of an abnormality with the estimation apparatus 10 according to the present embodiment in the estimation phase will be described with reference to FIG. 4. FIG. 4 is a flowchart illustrating an exemplary process of estimating a location or a cause of an abnormality according to the present embodiment. It should be noted that hereinafter, it is assumed that network configuration data and pieces of observed data collected by the collection unit 101 are stored in the network data DB 201. In addition, it is also assumed that the values of the states yⱼ of the pieces of observed data j collected by the collection unit 101 are calculated, and the pieces of observed data j and their states yⱼ are associated with each other to be stored in the network data DB 201.

Step S201: First, the user interface unit 107 receives the designation of a causal model to be used for estimating a location or a cause of an abnormality. That is, the user interface unit 107 receives the designation of one of the rule-based causal model, the data-driven causal model, or the causal model combining the rule-based causal model and the data-driven causal model.

Step S202: Next, the estimation unit 106 obtains from the network data DB 201 pieces of observed data j, their states yⱼ, and the network configuration data to be used for estimating a location or a cause of an abnormality. Herein, it is considered that pieces of observed data j when some abnormality has occurred in the communication network system are obtained as the pieces of observed data j, for example.

Step S203: Next, the estimation unit 106 estimates a location or a cause of an abnormality with the causal model designated in step S201 described above, using the states j of the pieces of observed data j obtained in step S202 described above. That is, the estimation unit 106 estimates an apparatus (or a cause) corresponding to xᵢ having the maximum posterior probability as a location of an abnormality (or a cause of an abnormality).

Step S204: The user interface unit 107 outputs the results of estimation (that is, the location or the cause of the abnormality and its probability) of step S203 described above to a display, for example, to present the results to a user.

Accordingly, in the estimation phase, the estimation apparatus 10 according to the present embodiment can estimate a location or a cause of an abnormality using the rule-based causal model, the data-driven causal model, or the causal model combining these. Further, the estimation apparatus 10 according to the present embodiment can, even when the network topology of the communication network system capable of obtaining various types of observed data changes frequently or observed data obtained from the communication network system changes frequently, estimate a location or a cause of an abnormality in the communication network system by using the causal model combining the rule-based causal model and the data-driven causal model.

### Hardware Configuration

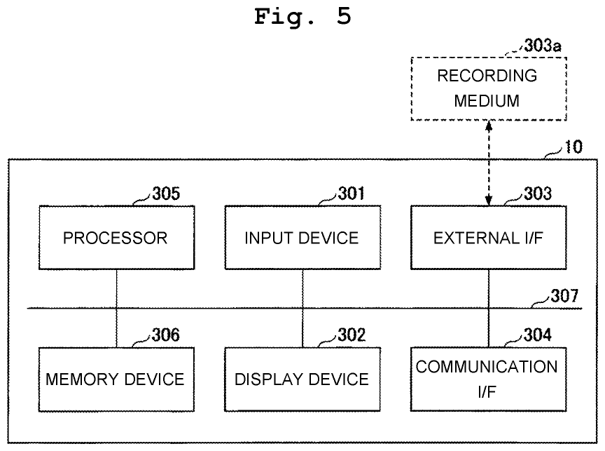

Finally, the hardware configuration of the estimation apparatus 10 according to the present embodiment will be described with reference to FIG. 5. FIG. 5 is a diagram illustrating an exemplary hardware configuration of the estimation apparatus 10 according to the present embodiment.

As illustrated in FIG. 5, the estimation apparatus 10 according to the present embodiment is implemented with a common computer or computer system, and includes an input device 301, a display device 302, an external I/F 303, a communication I/F 304, a processor 305, and a memory device 306. Such pieces of hardware are connected via a bus 307 so as to be capable of communicating with each other.

The input device 301 is a keyboard, a mouse, or a touch panel, for example. The display device 302 is a display, for example. It should be noted that the estimation apparatus 10 may not include at least one of the input device 301 and the display device 302.

The external I/F 303 is an interface with an external device, such as a recording medium 303a. The estimation apparatus 10 can read data from or write data to the recording medium 303a via the external I/F 303, for example. The recording medium 303a may store one or more programs that implement the functional units (i.e., the collection unit 101, the rule-based causal model construction unit 102, the division unit 103, the data-driven causal model construction unit 104, the causal model modification unit 105, the estimation unit 106, and the user interface unit 107) of the estimation apparatus 10, for example. It should be noted that examples of the recording medium 303a include a compact disc (CD), a digital versatile disk (DVD), a secure digital memory card (SD memory card), and a universal serial bus (USB) memory card.

The communication I/F 304 is an interface for connecting the estimation apparatus 10 to a communication network. It should be noted that one or more programs that implement the functional units of the estimation apparatus 10 may be obtained (i.e., downloaded) from a predetermined server device, for example, via the communication I/F 304.

The processor 305 includes various arithmetic units, such as a CPU, for example. The functional units of the estimation apparatus 10 are implemented through processes executed by the processor 305 based on one or more programs stored in the memory device 306, for example.

The memory device 306 includes various storage devices, such as a hard disk drive (HDD), a solid state drive (SSD), a random access memory (RAM), a read only memory (ROM), and a flash memory, for example. Each of the DBs (i.e., the network data DB 201 and the causal model DB 202) of the estimation apparatus 10 can be implemented with the memory device 306. It should be noted that at least one of the DBs may be implemented with a storage device (for example, a database server) connected to the estimation apparatus 10 via a communication network.

With the estimation apparatus 10 according to the present embodiment having the hardware configuration illustrated in FIG. 5, it is possible to implement the process of constructing a causal model and the process of estimating a location or a cause of an abnormality described above. It should be noted that the hardware configuration illustrated in FIG. 5 is only exemplary, and thus, the estimation apparatus 10 may have other hardware configurations. For example, the estimation apparatus 10 may include a plurality of processors 305 or a plurality of memory devices 306.

The present invention is not limited to the embodiment specifically disclosed above, and can be modified or changed in various ways or combined with the existing techniques without departing from the scope of the claims.

### Reference Signs List

10 Estimation apparatus

101 Collection unit

102 Rule-based causal model construction unit

103 Division unit

104 Data-driven causal model construction unit

105 Causal model modification unit

106 Estimation unit

107 User interface unit

201 Network data DB

202 Causal model DB

301 Input device

302 Display device

303 External I/F

303a Recording medium

304 Communication I/F

305 Processor

306 Memory device

307 Bus

1. A model construction apparatus comprising:
a processor; and
a memory storing program instructions that cause the processor to:
receive pieces of observed data from a communication network system that is a target for estimation of a location or a cause of an abnormality;
divide the received pieces of observed data into a plurality of clusters according to types of information represented by the respective pieces of observed data;
determine, for each location or each cause of an abnormality, a representative value as representative observed data for each of the plurality of clusters; and
construct, using the representative observed data, a first causal model for estimating the location or the cause of the abnormality from the pieces of observed data based on a rule-based method.

2. The model construction apparatus according to claim 1, wherein the program instructions further cause the processor to:
calculate a value representing a relationship between pieces of observed data when the communication network system is in a normal state among the received pieces of observed data;
calculate, using the value representing the relationship, a first conditional probability representing a relationship between a location or a cause of an abnormality in the communication network system and the pieces of observed data when the communication network system is in the normal state;
calculate, using pieces of observed data when the communication network system is in an abnormal state, a second conditional probability representing a relationship between the location or the cause of the abnormality and the pieces of observed data when the communication network system is in the abnormal state, based on a data-driven method; and
construct a second causal model for estimating the location or the cause of the abnormality from the pieces of observed data, using the first conditional probability and the second conditional probability.

3. The model construction apparatus according to claim 2, wherein the program instructions further cause the processor to construct a third causal model by modifying the first causal model based on the second causal model.

4. An estimation apparatus comprising:
a processor; and
a memory storing program instructions that cause the processor to:
receive pieces of observed data from a communication network system that is a target for estimation of a location or a cause of an abnormality;
store, into the memory, a causal model for estimating the location or the cause of the abnormality, the causal model including a first causal model constructed based on a rule-based method, a second causal model constructed based on a data-driven method, and a third causal model combining the first causal model and the second causal model; and
estimate, using the pieces of observed data, a location or a cause of an abnormality in the communication network system based on one of the first causal model, the second causal model, or the third causal model stored in the memory.

5. A model construction method comprising the following executed by a computer:
receiving pieces of observed data from a communication network system that is a target for estimation of a location or a cause of an abnormality;
dividing the received pieces of observed data into a plurality of clusters according to types of information represented by the respective pieces of observed data;
determining, for each location or each cause of an abnormality, a representative value as representative observed data for each of the plurality of clusters; and
constructing, using the representative observed data, a first causal model for estimating the location or the cause of the abnormality from the pieces of observed data based on a rule-based method.

6. (canceled)
